(19) United States
(12) Patent Application Publication
(10) Pub. No.: US 2013/0118551 A1
(43) Pub. Date: May 16, 2013

(54) COOLING CONTROL APPARATUS, PROGRAM, AND SOLAR CELL SYSTEM

(71) Applicant: Sony Corporation, Tokyo (JP)

(72) Inventor: Yoichiro Sako, Tokyo (JP)

(73) Assignee: Sony Corporation, Tokyo (JP)

(21) Appl. No.: 13/670,533

(22) Filed: Nov. 7, 2012

(30) Foreign Application Priority Data
Nov. 14, 2011 (JP) 2011-248856

(51) Int. Cl. H01L 31/052; F25D 29/00

(52) U.S. Cl. 136/246; 62/178

(57) ABSTRACT

There is provided a cooling control apparatus including a measurement unit that acquires a measured value of a power generation amount of a solar cell, and a cooling control unit that controls an intensity of cooling performed by a cooling mechanism of the solar cell in accordance with a relation between an expected value of the power generation amount of the solar cell and a measured value obtained by the measurement unit.

### BACKGROUND

The present disclosure relates to a cooling control apparatus, a program, and a solar cell system.

In recent years, solar cells capable of directly converting solar energy into electric energy have come into wide use as power generation apparatuses for environmental protection. A solar cell is generally made of a semiconductor material such as silicon, CuInGaSe, CdTe, or GaAs. Therefore, an output voltage of a solar cell deteriorates with an increase in the internal temperature of the solar cell. That is, the solar cell has the characteristics of a semiconductor, since power generation efficiency deteriorates. For example, the power generation efficiency of a solar cell panel deteriorates from 13 o'clock to 15 o'clock at which time the temperature is the highest during summer season. However, since a period of time from 13 o'clock to 15 o'clock in the summer is a power consumption peak period of time at individual corporations and houses, the maximum efficient power generation is preferably realized during this period of time.

The deterioration in the power generation efficiency can be improved by cooling the solar cell. However, solar cell systems currently in wide use do not include a mechanism that actively cools the solar cell. For this reason, the solar cell is cooled by natural precipitation or wind, or by sprinkling water manually.

From such a viewpoint, Japanese Patent No. 3751013 discloses a photovoltaic apparatus that includes a mechanism that automatically cools a solar cell. Specifically, in the photovoltaic apparatus, a water supplying unit sprinkles water on the surface of the solar cell to cool the solar cell using evaporation heat of the sprinkled water.

### SUMMARY

It is desirable to perform cooling control of a solar cell more suitably in a solar cell system.

According to an embodiment of the present disclosure, there is provided a cooling control apparatus including: a measurement unit that acquires a measured value of a power generation amount of a solar cell; and a cooling control unit that controls an intensity of cooling performed by a cooling mechanism of the solar cell in accordance with a relation between an expected value of the power generation amount of the solar cell and a measured value obtained by the measurement unit.

According to another embodiment of the present disclosure, there is provided a program for causing a computer to function as: a measurement unit that acquires a measured value of a power generation amount of a solar cell; and a cooling control unit that controls an intensity of cooling performed by a cooling mechanism of the solar cell in accordance with a relation between an expected value of the power generation amount of the solar cell and a measured value obtained by the measurement unit.

According to still another embodiment of the present disclosure, there is provided a solar cell system including: a solar cell; a measurement unit that acquires a measured value of a power generation amount of the solar cell; a cooling mechanism that cools the solar cell; and a cooling control unit that controls an intensity of cooling performed by the cooling mechanism of the solar cell in accordance with a relation between an expected value of the power generation amount of the solar cell and a measured value obtained by the measurement unit.

According to the embodiments of the present disclosure described above, it is possible to perform the cooling control of the solar cell more suitably.

### BRIEF DESCRIPTION OF THE DRAWINGS

FIG. 1 is a diagram illustrating the configuration of a solar cell system according to an embodiment of the present disclosure;

FIG. 2 is a functional block diagram illustrating the configuration of a cooling control apparatus according to a first embodiment;

FIG. 3 is a flowchart illustrating an operation of the cooling control apparatus according to the first embodiment;

FIG. 4 is a functional block diagram illustrating the configuration of a cooling control apparatus according to a second embodiment;

FIG. 5 is a diagram illustrating a specific example of a measurement database;

and

FIG. 6 is a flowchart illustrating an operation of the cooling control apparatus according to the second embodiment;

### DETAILED DESCRIPTION OF THE EMBODIMENTS

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

Throughout the specification and the drawings, different letters are sometimes given after the same reference numeral of a plurality of constituent elements having substantially the same functional configuration to distinguish the constituent elements from each other. However, when it is not necessary to particularly distinguish a plurality of constituent elements having substantially the same functional configuration, the same reference numerals are given.

Hereinafter, embodiments of the present disclosure will be described in the order of the following items.

1. Basic Configuration of Solar Cell System

2. First Embodiment

2-1. Configuration of Cooling Control Apparatus According to First Embodiment

2-2. Operation of Cooling Control Apparatus According to First Embodiment

3. Second Embodiment

3-1. Configuration of Cooling Control Apparatus According to Second Embodiment

3-2. Operation of Cooling Control Apparatus According to Second Embodiment

4. Conclusion

### 1. Basic Configuration of Solar Cell System

A technology according to embodiments of the present disclosure can be realized in various ways, as described in this specification. A cooling control apparatus (20) according to embodiments of the present disclosure includes a measurement unit (210) that measures a power generation amount of a solar cell (10); and a cooling control unit (230 or 234) that controls an intensity of cooling performed by a cooling mechanism (a watering mechanism 30) of the solar cell in accordance with a relation between an expected value of the power generation amount of the solar cell and a measured value obtained by the measurement unit.

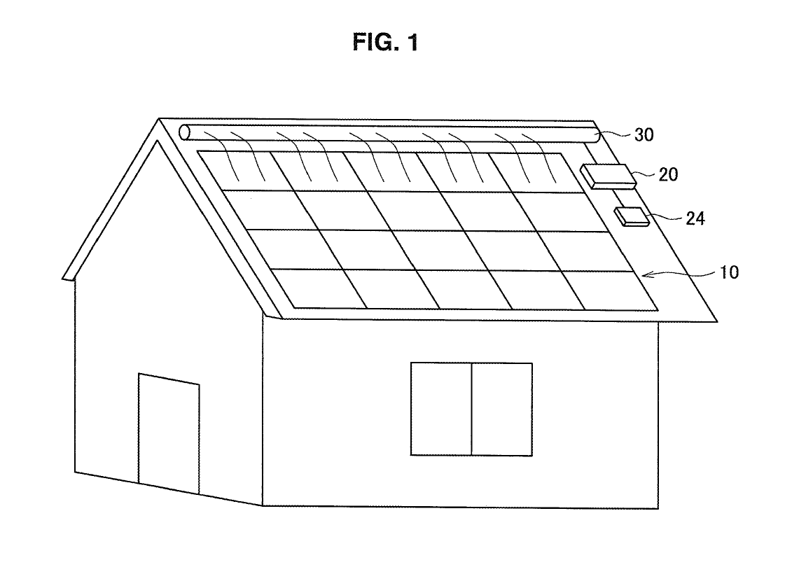

First, a basic configuration of a solar cell system including such a cooling control apparatus will be described below with reference to FIG. 1.

FIG. 1 is a diagram illustrating the configuration of a solar cell system according to an embodiment of the present disclosure. As shown in FIG. 1, the solar cell system according to the embodiment of the present disclosure includes a solar cell 10, a cooling control apparatus 20, a sensor apparatus 24, and a watering mechanism 30.

The solar cell 10 has a function of directly converting solar energy into electric energy. The solar cell 10 is generally installed on the roof a building or a house, as shown in FIG. 1. The solar cell 10 is generally made of a semiconductor material such as silicon, CuInGaSe, CdTe, or GaAs. Therefore, an output voltage deteriorates with an increase in the internal temperature of the solar cell 10. That is, the solar cell 10 has the characteristics of a semiconductor, since generation efficiency deteriorates. According to a study, deterioration in the power generation efficiency caused due to an increase in the internal temperature is estimated to be 10% from December to February, 15% from March to May and from September to November, and 20% from June to August.

The technology according to the embodiments of the present disclosure is devised in view of the deterioration in the power generation efficiency caused due to the increase in the internal temperature. According to the embodiments of the present disclosure, it is possible to improve the deterioration in the power generation efficiency of the solar cell 10 caused due to the increase in the internal temperature.

The watering mechanism 30 is an example of a cooling mechanism that cools the solar cell 10. The watering mechanism 30 has a function of cooling the solar cell 10 under the control of the cooling control apparatus 20. Specifically, water flows inside the watering mechanism 30 or a water-supply pipe is installed in the watering mechanism 30. The water-supply pipe has watering holes in a plurality of portions thereof. The water in the water-supply pipe flows out from the watering holes, and thus the surface of the solar cell 10 becomes wet. Thus, the solar cell 10 is cooled by the water temperature and evaporation heat of the water.

In the specification, the watering mechanism 30 will be exemplified as the cooling mechanism, but the cooling mechanism is not limited to the watering mechanism 30. For example, the cooling mechanism may be a heat pipe cooling mechanism or a mechanism that uses a cooling medium such as a Peltier cooling element.

The sensor apparatus 24 includes at least one sensor module. The sensor apparatus 24 supplies an external environment detection result to the cooling control apparatus 20. For example, the sensor apparatus 24 may include a temperature sensor that detects temperature, a humidity sensor that detects humidity, a weather sensor that detects weather, an optical sensor that detect an amount of light, or a temperature sensor that detects the internal temperature of the solar cell 10.

The cooling control apparatus 20 controls the watering performed by the watering mechanism 30, that is, the cooling performed for the watering mechanism 30 to cool the solar cell 10. For example, the cooling control apparatus 20 can control an amount of water sprinkled from the watering mechanism 30 by controlling an amount of water or a supply time interval of water supplied to the water-supply pipe included in the watering mechanism 30 and controlling opening and closing of the watering holes formed in the water-supply pipe.

A cooling control apparatus 20-1 according to a first embodiment of the present disclosure can perform cooling control of the solar cell 10 suitably using the watering mechanism 30 based on the external environment detection result supplied from the sensor apparatus 24. Further, a cooling control apparatus 20-2 according to a second embodiment of the present disclosure can perform cooling control of the solar cell 10 suitably using the watering mechanism 30 based on a previous statistical value. Hereinafter, the first and second embodiments of the present disclosure will be sequentially described in detail.

### 2. First Embodiment

### 2-1. Configuration of Cooling Control Apparatus According to First Embodiment

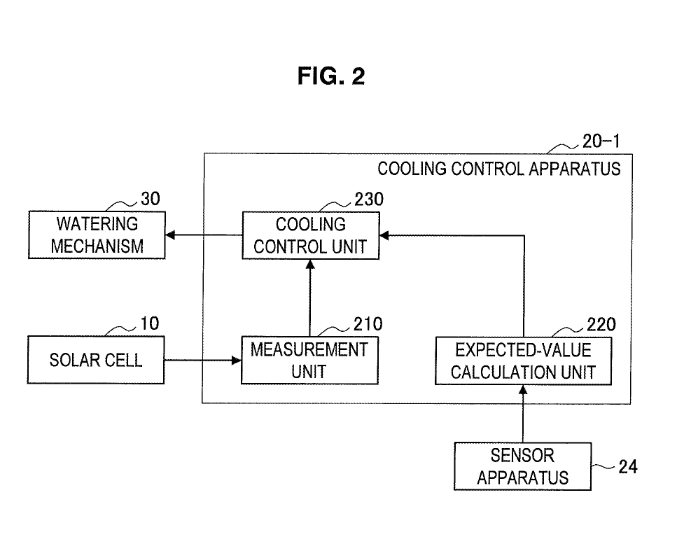

FIG. 2 is a functional block diagram illustrating the configuration of the cooling control apparatus 20-1 according to the first embodiment. As shown in FIG. 2, the cooling control apparatus 20-1 according to this embodiment includes a measurement unit 210, an expected-value calculation unit 220, and a cooling control unit 230.

### Measurement Unit

The measurement unit 210 measures an actual power generation amount of the solar cell 10. The measurement unit 210 may measure a power generation amount of the entire solar cell 10 or may measure a power generation amount of some cells of the solar cell 10. When the power generation amount of the solar cell 10 is measured by an external apparatus, the measurement unit 210 may be notified of the power generation amount of the solar cell 10 by the external apparatus.

### Expected-Value Calculation Unit

The expected-value calculation unit 220 calculates an expected value of the power generation amount of the solar cell 10. For example, the expected-value calculation unit 220 may calculate the expected value (which is a value obtained without consideration of efficiency deterioration caused due to an increase in the internal temperature) of the amount of generated power in accordance with the current amount of light supplied from the sensor apparatus 24, the area of the solar cell 10, the element characteristics of the solar cell 10, or the like. When an optical sensor in the sensor apparatus 24 is disposed in the same plane as the solar cell 10, an incident angle on the optical sensor is the same as an incident angle on the solar cell 10. Therefore, when the expected value of the power generation amount is calculated based on the amount of light detected by the optical sensor, the incident angle may not be considered. Conversely, when the optical sensor in the sensor apparatus 24 is disposed in a plane different from that of the solar cell 10, the incident angle on the optical sensor is different from the incident angle on the solar cell 10. Therefore, the expected value of the power generation amount may be calculated in consideration of the difference between the incident angles from the amount of light detected by the optical sensor. Further, the nominal maximum output of the solar cell 10 may be used as the expected value of the power generation amount. In this case, the cooling control apparatus 20-1 may not include the expected-value calculation unit 220.

### Cooling Control Unit

The cooling control unit 230 controls the intensity of the cooling of the watering mechanism 30 in accordance with the relation between the expected value of the power generation amount of the solar cell 10 calculated by the expected-value calculation unit 220 and the measured value of the actual power generation amount obtained by the measurement unit 210. Specifically, when the measured value of the power generation amount is less than the expected value of the power generation amount, there is a probability that the power generation efficiency of the solar cell 10 may deteriorate due to an increase in the internal temperature of the solar cell 10. Therefore, the cooling control unit 230 intensifies the cooling of the watering mechanism 30 by a difference between the expected value and the measured value. Further, the cooling control unit 230 can intensify or weaken the cooling by controlling the amount of water per unit time sprinkled by the watering mechanism 30 or a watering time (that is, a cooling time) of the watering mechanism 30. Further, the intensity of the cooling of the watering mechanism 30 controlled by the cooling control unit 230 may be set in a stage manner or a continuous manner.

When an improvement expected by intensifying the cooling of the watering mechanism 30 is not reflected on the measured value within a predetermined time such as one hour after start of the cooling of the watering mechanism 30, the power generation efficiency is considered to deteriorate due to another cause, such as breakdown of the solar cell 10, other than the increase in the internal temperature of the solar cell 10. In this case, since the purpose to maintain the cooling of the watering mechanism 30 is little, the cooling control unit 230 may weaken or stop the cooling of the watering mechanism 30.

When the weather is rainy, the surface of the solar cell 10 is already wet. Therefore, the effect of the cooling of the watering mechanism 30 is considered to be substantially little. Therefore, when the weather is rainy, the cooling control unit 230 may cause the watering mechanism 30 not to cool the solar cell 10. Further, when the amount of light and the measured value of the power generation amount are small, the weather is considered to be rainy. Therefore, based on the amount of light or the measured value of the power generation amount, the cooling control unit 230 may determine whether the weather is rainy. For example, when the current amount of light supplied from the sensor apparatus 24 is less than a predetermined value or the measured value of the power generation amount is less than a predetermined value (for example, 20% of the nominal maximum power), the weather is considered to be rainy. Therefore, the cooling control unit 230 may cause the watering mechanism 30 not to cool the solar cell 10.

Further, as a comparative example of this embodiment, control can be considered to be performed such that the considerable amount of water is sprinkled on a summer day or a high temperature day. However, when it rains immediately before a summer day or a high temperature day, the internal temperature of the solar cell 10 is low, and thus the watering mechanism 30 may unnecessarily sprinkle water. Accordingly, since the control according to this embodiment is performed based on the measured value of the actual power generation amount, the cooling (watering) of the solar cell 10 can be controlled more suitably.

### 2-2. Operation of Cooling Control Apparatus According to First Embodiment

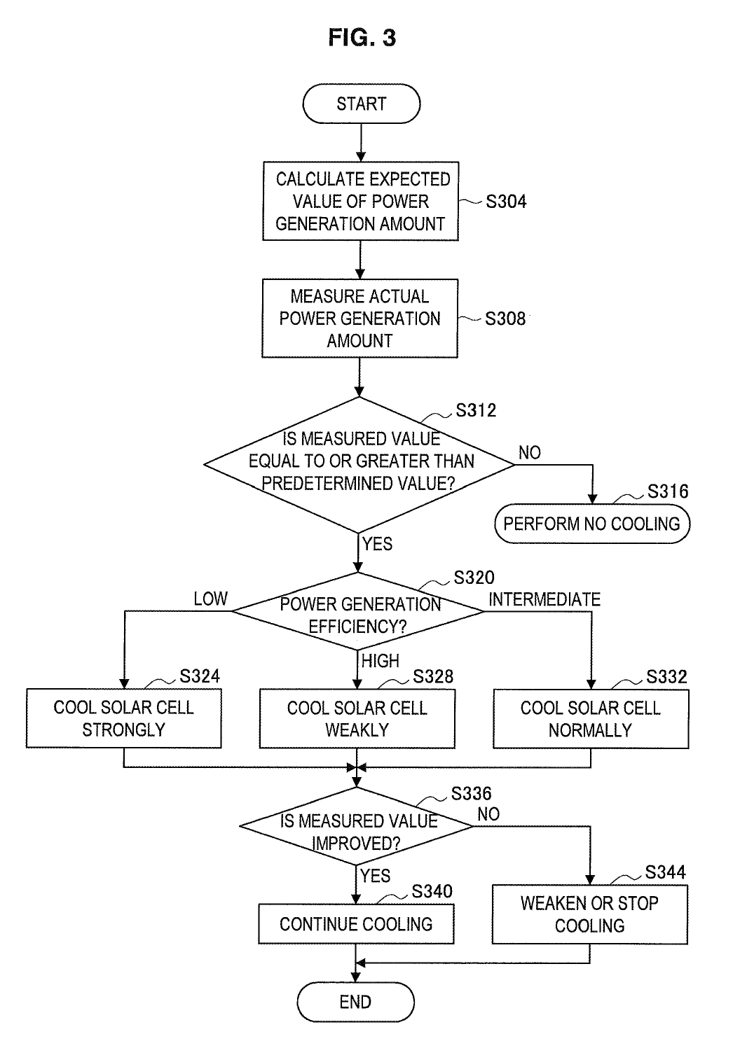

The configuration of the cooling control apparatus 20-1 according to the first embodiment has been described. Next, an operation of the cooling control apparatus 20-1 according to the first embodiment will be described with reference to FIG. 3.

FIG. 3 is a flowchart illustrating the operation of the cooling control apparatus 20-1 according to the first embodiment. As shown in FIG. 3, the expected-value calculation unit 220 of the cooling control apparatus 20-1 first calculates the expected value of the power generation amount of the solar cell 10, for example, based on the current amount of light supplied from the sensor apparatus 24 (S304). The measurement unit 210 measures the actual power generation amount of the solar cell 10 (S308).

Then, the cooling control unit 230 determines whether the measured value of the power generation amount measured by the measurement unit 210 is equal to or greater than a predetermined value (S312). When the measured value is less than the predetermined value, that is, it is determined that the weather is rainy, the cooling control unit 230 causes the cooling mechanism not to cool the solar cell 10 (S316).

Conversely, when the measured value is equal to or greater than the predetermined value (S312), the cooling control unit 230 evaluates the degree of the power generation efficiency which is expressed as a ratio of the measured value to the expected value calculated in step S304 (S320). For example, the cooling control unit 230 may evaluate the degree of the power generation efficiency based on first and second threshold values.

### (Example of Evaluation of Power Generation Efficiency)

Power Generation Efficiency<First Threshold Value: Power Generation Efficiency=Low

First Threshold Value Power≦Generation Efficiency<Second Threshold Value: Power Generation Efficiency=Intermediate

Second Threshold Value≦Power Generation Efficiency: Power Generation Efficiency=High

(where First Threshold Value<Second Threshold Value)

When the power generation efficiency is low, the cooling control unit 230 causes the watering mechanism 30 to cool the solar cell 10 strongly (S324). When the power generation efficiency is high, the cooling control unit 230 causes the watering mechanism 30 to cool the solar cell 10 weakly (S328). When the power generation efficiency is intermediate, the cooling control unit 230 causes the watering mechanism 30 to cool the solar cell 10 normally (S332).

Thereafter, when an improvement expected by intensifying the cooling of the watering mechanism 30 is reflected on the measured value within the predetermined time (SS336), the cooling control unit 230 causes the watering mechanism 30 to continue cooling the solar cell 10 (S340). Conversely, when the improvement expected by intensifying the cooling of the watering mechanism 30 is not reflected on the measured value within the predetermined time, the power generation efficiency is considered to deteriorate due to another cause other than the increase in the internal temperature of the solar cell 10. Therefore, the cooling control unit 230 weakens or stops the cooling of the watering mechanism 30 (S344).

### 3. Second Embodiment

The first embodiment of the present disclosure has been described. Next, a second embodiment of the present disclosure will be described. According to the second embodiment of the present disclosure, it is possible to control the cooling, for example, based on the current external environment and a measurement database obtained by accumulating the relation between the measured value and an external environment in the measurement of the measured value, as in the first embodiment.

### 3-1. Configuration of Cooling Control Apparatus According to Second Embodiment

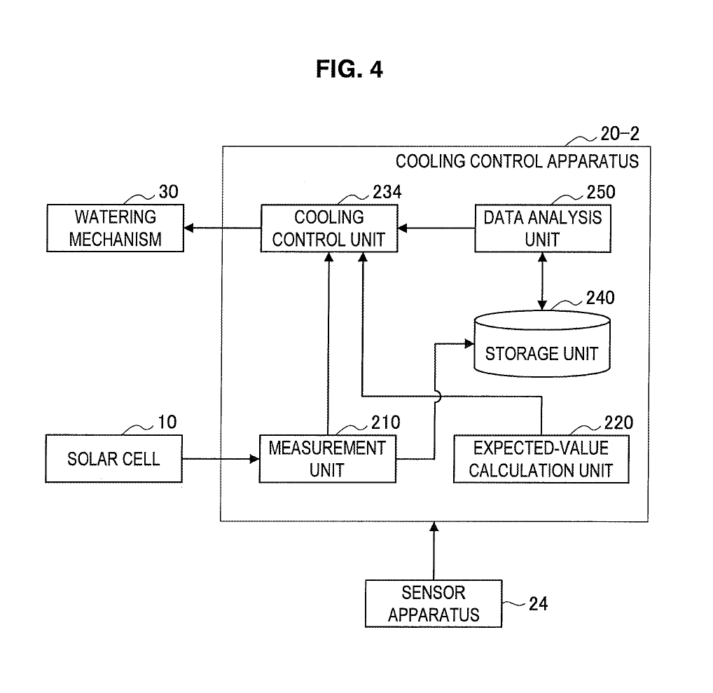

FIG. 4 is a functional block diagram illustrating the configuration of a cooling control apparatus 20-2 according to the second embodiment. As shown in FIG. 4, the cooling control apparatus 20-2 according to this embodiment includes a measurement unit 210, an expected-value calculation unit 220, a cooling control unit 234, a storage unit 240, and a data analysis unit 250. Since the measurement unit 210 and the expected-value calculation unit 220 are the same as those of the first embodiment, the detailed description thereof will not be repeated here.

### Storage Unit

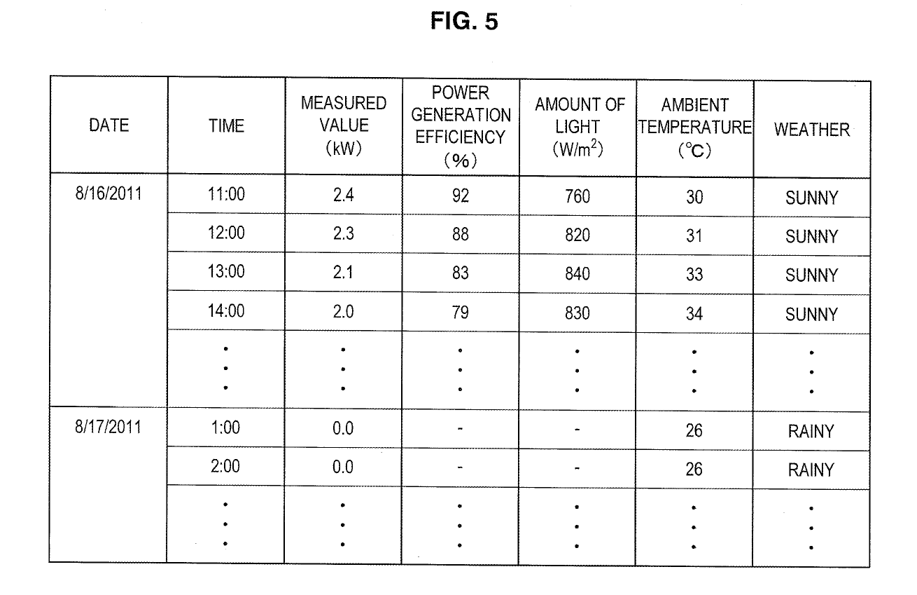

The storage unit 240 stores a measurement database in which a measured value of an actual power generation amount measured by the measurement unit 210 is associated with an external environment in the measurement of the measured value. Next, a specific example of the measurement database will be described below with reference to FIG. 5.

FIG. 5 is a diagram illustrating the specific example of the measurement database. In the specific example of the measurement database shown in FIG. 5, external environments such as a date, a time, an amount of light, ambient temperature, and weather can be associated with the measured value of the power generation amount and the power generation efficiency. In the measurement database, season, the internal temperature of the solar cell 10, and other external environmental factors such as a sunrise/sunset time may be included in addition to the above-mentioned external environmental factors or instead of some of the above-mentioned external environmental factors. From the example shown in FIG. 5, it can be understood that the power generation efficiency gradually deteriorates from about 11 o'clock on 16 August, which is a sunny summer day.

FIG. 5 shows the example in which measured data measured in intervals of 1 hour throughout each day is accumulated in the measurement database, but the accumulated measured data is not limited thereto. For example, the measurement interval of the measured data may be 5 minutes, 30 minutes, 2 hours, or the like. Further, the measured data corresponding to a week may be accumulated in the measurement database or the measured data corresponding to one month or one year may be accumulated. The measured data may be measured every second day, every one week, or at irregular intervals, rather than every day. Further, the measurement database may be obtained through actual measurement of the cooling control apparatus 20-2 or may be initially set in manufacture or installation. As will be described below, the storage unit 240 stores control rules of generation of the data analysis unit 250.

The storage unit storing the measurement database may be a storage medium such as a non-volatile memory, a magnetic disk, an optical disc, or a magneto-optical (MO) disc. Examples of the non-volatile memory include a flash memory, an SD card, a micro-SD card, a USB memory, an electrically erasable programmable read-only memory (EEPROM), and an erasable programmable ROM (EPROM). Examples of the magnetic disk include a hard disk and a disk-shaped magnetic disk. Examples of the optical disc include a compact disc (CD), a digital versatile disc (DVD), and a Blu-ray Disc (BD) (registered trademark).

### Data Analysis Unit

The data analysis unit 250 creates the control rules that define the relation between at least one external environmental factor and the contents of the cooling control by analyzing the contents of the measurement database. For example, the data analysis unit 250 may create the following control rules by analyzing the measurement database.

### Examples of Control Rule Based on Season

Summer: Strong Cooling

Spring and Fall: Weak Cooling

Winter: No Cooling

### Examples of Control Rule Based on Weather

Sunny: Strong Cooling

Cloudy: Weak Cooling

Rainy: No Cooling

### Examples of Control Rule Based on Time

Peak Time (for example, 13 o'clock to 15 o'clock): Strong Cooling

Time Other than Peak Time of Day: Weak Cooling

Time Other than Peak Time of Night: No Cooling

### Examples of Control Rule Based on Ambient Temperature

30 Degrees or More: Strong Cooling, 20 Degrees or More and Less than 30 Degrees: Normal Cooling

10 Degrees or More and Less Than 20 Degrees: Weak Cooling, Less than 10 Degrees: No Cooling

Examples of Control Rule by Combination (case of Season=Summer)

Sunny+Peak Time: Strong Cooling

Sunny+Time Other than Peak Time of Day: Normal Cooling

Sunny+Time Other than Peak Time of Night: No Cooling

Cloudy+Peak Time: Normal Cooling

Cloudy+Time Other than Peak Time of Day: Weak Cooling

Cloudy+Time Other than Peak Time of Night: No Cooling

Rainy+Peak Time: No Cooling

Rainy+Time Other than Peak Time of Day: No Cooling

Rainy+Time Other than Peak Time of Night: No Cooling

Further, the data analysis unit 250 analyzes an external environment which is an indication of deterioration of the measured value (power generation efficiency) in the measurement database. For example, the data analysis unit 250 detects that the power generation efficiency deteriorates after 12 o'clock on 16 August from the measurement database shown in FIG. 5 and specifies the external environment of “11 o'clock of a sunny summer day” as an external environment which is an indication of deterioration of the power generation efficiency. Thus, this external environment is used in the prediction of the power generation efficiency deteriorating after the external environment occurs.

### Cooling Control Unit

The cooling control unit 234 controls the watering mechanism 30 such that the watering mechanism 30 cools the solar cell 10. Specifically, the cooling control unit 234 according to this embodiment operates in a first cooling control mode in which the measured value and the expected value of the power generation amount described in the first embodiment or in a second cooling control mode in which the measurement database stored in the storage unit 240 is used. Since the first cooling control mode is the same as the mode described in the first embodiment, the detailed description thereof will not be repeated here.

The cooling control unit 234 can operate in the second cooling control mode after the measurement database is accumulated in the storage unit 240 and the above-described control rules are created by the data analysis unit 250. The cooling control unit 234 operating in the second cooling control mode searches for the control rules indicating an external environment matching the current external environment and performs the cooling control in accordance with the contents of the control rules.

For example, when the current external environment is a sunny summer day and a time of 14 o'clock, the current external environment matches the control rule of “Sunny+Peak Time” of “Examples of Control Rule by Combination.” Therefore, the cooling control unit 234 may cause the watering mechanism 30 to strongly cool the solar cell 10.

The cooling control unit 234 may cause the watering mechanism 30 to strongly cool the solar cell 10 when the current external environment matches or is similar to an external environment which is an indication of deterioration of the power generation efficiency specified by the data analysis unit 250. In this configuration, it is possible to prevent the deterioration in the power generation efficiency in advance.

### 3-2. Operation of Cooling Control Apparatus According to Second Embodiment

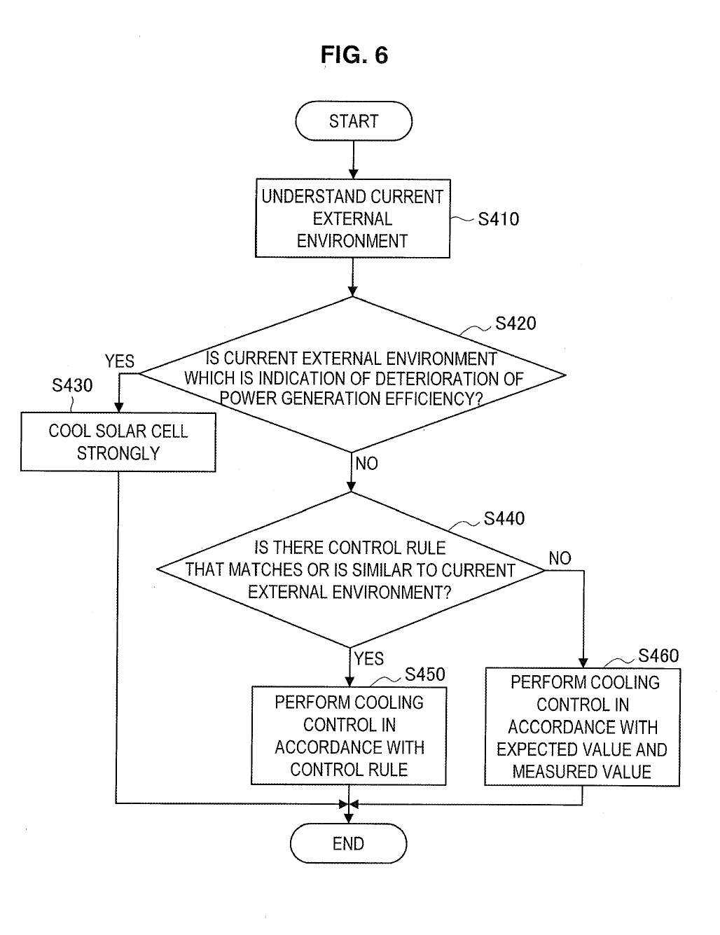

The cooling control apparatus 20-2 according to the second embodiment has been described. Next, an operation of the cooling control apparatus 20-2 according to the second embodiment will be described with reference to FIG. 6.

FIG. 6 is a flowchart illustrating the operation of the cooling control apparatus 20-2 according to the second embodiment. As shown in FIG. 6, the cooling control unit 234 of the cooling control apparatus 20-2 understands the current external environment based on the detection result or the like supplied from the sensor apparatus 24 (S410).

Then, when the current external environment matches or is similar to an external environment which is an indication of deterioration of the power generation efficiency specified by the data analysis unit 250 (S420), the cooling control unit 234 causes the watering mechanism 30 to strongly cool the solar cell 10 before the deterioration of the power generation efficiency (S430).

Conversely, when the external environment which is an indication of deterioration of the power generation efficiency neither matches nor is similar to the current external environment, the cooling control unit 234 searches for a control rule regarding the external environment matching or similar to the current external environment (S440).

When the control rule regarding the external environment matching or similar to the current external environment is present, the cooling control unit 234 controls the watering mechanism 30 to cool the solar cell 10 in accordance with the control rule (S450). Conversely, when the control rule regarding the external environment matching or similar to the current external environment is not present, the cooling control unit 234 performs the cooling control in accordance with the expected value and the measured value of the power generation amount, as described in the first embodiment (S460).

### 4. Conclusion

According to the embodiments of the present disclosure, as described above, it is possible to suppress the deterioration in the power generation efficiency caused due to the increase in the internal temperature of the solar cell 10 by controlling the cooling of the solar cell 10. Further, since the power generation efficiency is improved in a hot period of time in summer, an additional advantage of reducing the use amount of commercial power at a peak time.

It should be understood by those skilled in the art that various modifications, combinations, sub-combinations and alterations may occur depending on design requirements and other factors insofar as they are within the scope of the appended claims or the equivalents thereof.

For example, the steps of the operation of the cooling control apparatus 20 according to the embodiments of the present disclosure may not necessarily be performed chronologically in the order described in the flowcharts. For example, the steps of the operation of the cooling control apparatus 20 may be performed in an order different from the order described in the flowcharts or may be performed in parallel.

It is possible to create a computer program causing the hardware such as a CPU, a ROM, a RAM, or the like included in the cooling control apparatus 20 to execute the same functions as those of the units of the above-described cooling control apparatus 20. Further, a storage medium that stores the computer program is provided.

Additionally, the present technology may also be configured as below.
(1) A cooling control apparatus including:

a measurement unit that acquires a measured value of a power generation amount of a solar cell; and

a cooling control unit that controls an intensity of cooling performed by a cooling mechanism of the solar cell in accordance with a relation between an expected value of the power generation amount of the solar cell and a measured value obtained by the measurement unit.
(2) The cooling control apparatus according to (1), further including:

an expected-value calculation unit that calculates the expected value of the power generation amount of the solar cell based on an amount of light detected by an optical sensor.
(3) The cooling control apparatus according to (1) or (2), wherein the cooling control unit intensifies the cooling performed by the cooling mechanism by a difference between the expected value and the measured value.
(4) The cooling control apparatus according to any one of (1) to (3), wherein the cooling control unit does not cause the cooling mechanism to perform the cooling when the measured value is less than a predetermined value.
(5) The cooling control apparatus according to any one of (1) to (4), wherein the cooling control unit weakens or stops the cooling performed by the cooling mechanism when an improvement expected from the intensity of the cooling performed by the cooling mechanism is not reflected on the measured value.
(6) The cooling control apparatus according to (1), further including:

a storage unit that stores a measurement database in which the measured value is associated with an external environment at a time of the measurement.
(7) The cooling control apparatus according to (6), wherein the cooling control unit has a control mode in which the intensity of the cooling performed by the cooling mechanism of the solar cell is controlled based on a current external environment and the measurement database.
(8) The cooling control apparatus according to (7), further including:

a data analysis unit that analyzes an external environment which is an indication of deterioration of the measured value in the measurement database,

wherein the cooling control unit intensifies the cooling performed by the cooling mechanism when a current external environment is similar to or matches an external environment analyzed by the data analysis unit.
(9) The cooling control apparatus according to (7) or (8), wherein the external environment includes at least one of time, season, weather, ambient temperature, or an internal temperature of the solar cell.
(10) The cooling control apparatus according to any one of (1) to (9), wherein the cooling mechanism is at least one of a watering mechanism, a heat pipe cooling mechanism, or a mechanism using a cooling medium.
(11) A program for causing a computer to function as:

a measurement unit that acquires a measured value of a power generation amount of a solar cell; and

a cooling control unit that controls an intensity of cooling performed by a cooling mechanism of the solar cell in accordance with a relation between an expected value of the power generation amount of the solar cell and a measured value obtained by the measurement unit.
(12) A solar cell system including:

a solar cell;

a measurement unit that acquires a measured value of a power generation amount of the solar cell;

a cooling mechanism that cools the solar cell; and

a cooling control unit that controls an intensity of cooling performed by the cooling mechanism of the solar cell in accordance with a relation between an expected value of the power generation amount of the solar cell and a measured value obtained by the measurement unit.

The present disclosure contains subject matter related to that disclosed in Japanese Priority Patent Application JP 2011-248856 filed in the Japan Patent Office on Nov. 14, 2011, the entire content of which is hereby incorporated by reference.

What is claimed is:

1. A cooling control apparatus comprising:
a measurement unit that acquires a measured value of a power generation amount of a solar cell; and
a cooling control unit that controls an intensity of cooling performed by a cooling mechanism of the solar cell in accordance with a relation between an expected value of the power generation amount of the solar cell and a measured value obtained by the measurement unit.

2. The cooling control apparatus according to claim 1, further comprising:
an expected-value calculation unit that calculates the expected value of the power generation amount of the solar cell based on an amount of light detected by an optical sensor.

3. The cooling control apparatus according to claim 1, wherein the cooling control unit intensifies the cooling performed by the cooling mechanism by a difference between the expected value and the measured value.

4. The cooling control apparatus according to claim 1, wherein the cooling control unit does not cause the cooling mechanism to perform the cooling when the measured value is less than a predetermined value.

5. The cooling control apparatus according to claim 1, wherein the cooling control unit weakens or stops the cooling performed by the cooling mechanism when an improvement expected from the intensity of the cooling performed by the cooling mechanism is not reflected on the measured value.

6. The cooling control apparatus according to claim 1, further comprising:
a storage unit that stores a measurement database in which the measured value is associated with an external environment at a time of the measurement.

7. The cooling control apparatus according to claim 6, wherein the cooling control unit has a control mode in which the intensity of the cooling performed by the cooling mechanism of the solar cell is controlled based on a current external environment and the measurement database.

8. The cooling control apparatus according to claim 7, further comprising:
a data analysis unit that analyzes an external environment which is an indication of deterioration of the measured value in the measurement database,
wherein the cooling control unit intensifies the cooling performed by the cooling mechanism when a current external environment is similar to or matches an external environment analyzed by the data analysis unit.

9. The cooling control apparatus according to claim 7, wherein the external environment includes at least one of time, season, weather, ambient temperature, or an internal temperature of the solar cell.

10. The cooling control apparatus according to claim 1, wherein the cooling mechanism is at least one of a watering mechanism, a heat pipe cooling mechanism, or a mechanism using a cooling medium.

11. A program for causing a computer to function as:
a measurement unit that acquires a measured value of a power generation amount of a solar cell; and
a cooling control unit that controls an intensity of cooling performed by a cooling mechanism of the solar cell in accordance with a relation between an expected value of the power generation amount of the solar cell and a measured value obtained by the measurement unit.

12. A solar cell system comprising:
a solar cell;
a measurement unit that acquires a measured value of a power generation amount of the solar cell;
a cooling mechanism that cools the solar cell; and
a cooling control unit that controls an intensity of cooling performed by the cooling mechanism of the solar cell in accordance with a relation between an expected value of the power generation amount of the solar cell and a measured value obtained by the measurement unit.
